(19) United States
(12) Patent Application Publication
(10) Pub. No.: US 2007/0020390 A1
(43) Pub. Date: Jan. 25, 2007

(54) Supplying method of chemicals

(75) Inventor: Junichi Uchida, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/486,130

(22) Filed: Jul. 14, 2006

(30) Foreign Application Priority Data
Jul. 25, 2005 (JP) 2005-214038

(51) Int. Cl. C23C 16/00

(52) U.S. Cl. 427/248.1

(57) ABSTRACT

Even if a process cylinder of a CVD machine, wherein a chemical which is a starting material for CVD is stored, becomes empty, a chemical of the same kind can be filled into the process cylinder in a short time without exchanging the process cylinder. In a path made of a pipe wherein a chemical is supplied from a sealed fixed cylinder arranged in a chemical supplying device to a sealed process cylinder arranged in a CVD machine, the chemical in the fixed cylinder is pressured with He gas, thereby supplying the chemical from the fixed cylinder to the process cylinder. Next, the pressure in the process cylinder is lowered and then He gas is introduced from another path connected to the above-mentioned path and made of a pipe into the above-mentioned path, thereby pressuring the chemical present in the above-mentioned path.

### CROSS-REFERENCE TO RELATED APPLICATION

The present application claims priority from Japanese patent application No. 2005-214038 filed on Jul. 25, 2005, the content of which is hereby incorporated by reference into this application.

### BACKGROUND OF THE INVENTION

The present invention relates to a supplying technique of one or more chemicals, in particular, a technique useful for being applied to a supplying technique of a chemical having a low vapor pressure such as tetrakis(dimethylamino)titanium (TDMAT), a corrosive chemical, or a chemical which has toxicity, combustibility, pyrophoricity, or reactivity with air.

In the case of forming a film by use of chemical reaction in a chemical vapor deposition (CVD) machine or the like, a chemical such as TDMAT is used as the raw material thereof.

Japanese Unexamined Patent Publication No. 2001-49434 (paragraphs [0019] to [0020] and [0030], and FIGS. 1 and 2) discloses a technique in which: in a tetrakis(dialkylamino)titanium (TDAAT) supplying machine for supplying TDAAT as a raw material into a bubbling supplying device arranged near a CVD machine, the liquid surface of the raw material TDAAT is measured with an optical sensor; and at the time when the amount of TDAAT becomes small, TDAAT is newly filled thereinto.

Japanese Unexamined Patent Publication No. 2003-168651 (paragraphs [0024] to [0027] and [0030], and FIG. 1) discloses a technique in which at the time of starting-gas-exchange, wherein a new liquid-form starting gas for CVD is supplied into a starting material supplying container, an old starting gas remaining in a pipe for the starting gas is caused to pass via a bypass pipe, so as to be removed.

Japanese Unexamined Patent Publication No. 2002-130596 (paragraphs [0007] to [0008] and FIG. 1) discloses a technique in which in the supply of helium gas a flow rate control device is fitted into a path extending from a helium cylinder to a liquid helium container so as to control the flow rate of helium gas.

Japanese Unexamined Patent Publication No. 2001-32072 (paragraphs [0012] to [0018] and FIG. 2) and Japanese Unexamined Patent Publication No. 2000-197861 (paragraphs [0032] to [0040] and FIG. 1) each disclose a technique of performing the supply of TDMAT gas into a TDMAT-gas-supplying pipe in a machine using TDMAT and the purge of the gas from the pipe automatically through a programmed controller.

Japanese Unexamined Patent Publication No. 2000-167381 (paragraphs [0016] to [0017] and [0045], and FIG. 1) discloses a technique in which: the remaining amount of a starting gas in a bubbler for supplying the starting gas into a CVD machine is monitored with an ultrasonic sensor; and when the remaining amount comes to a small value, a new starting material is automatically supplied from a starting-gas-storing container thereinto.

### SUMMARY OF THE INVENTION

For example, transistors which constitute a large scale integration (LSI) produce a large effect onto, for example, contact resistance between a metal electrode and the transistors. For this reason, as a barrier metal for obtaining a low resistance contact, for example, a lamination structure composed of titanium (Ti) and titanium nitride (TiN) can be applied to the LSI.

As one process for producing the lamination of Ti/TiN, there is known a chemical vapor deposition (CVD) technique of using, as a starting material (raw material) for CVD, a chemical having a small vapor pressure, such as tetrakis(dimethylamino)titanium (TDMAT: Ti(N(CH₃)₂)₄). This CVD technique using TDMAT is a technique excellent in formability of a film onto, for example, side faces or the bottom face of a finely-formed contact.

For example, when a TiN film is formed in a reaction chamber in a CVD machine, a chemical which is a starting material for CVD, for example, TDMAT is supplied from a process cylinder, which is a sealed container arranged inside a cylinder cabinet in the CVD machine. FIG. 4 is an explanatory view illustrating an example of a CVD machine applied to a chemical supplying technique which is not a known technique but has been investigated by the present inventors.

The chemical supplying technique, which has been investigated by the inventors, is roughly described with reference to FIG. 4. For example, when a TiN film is formed in a reaction chamber 102 of a CVD machine 101, a chemical 103 which is a starting material for CVD, such as TDMAT, is supplied from a process cylinder 105, which is a sealed container arranged inside a cylinder cabinet 104 in the CVD machine 101.

As illustrated in FIG. 4, the cylinder cabinet 104 has: the process cylinder 105, in which the chemical 103 such as TDMAT is stored (fully put); and a pipe system made to comprise a manifold A 107 composed of pipes connected to the process cylinder 105 and valves. The cylinder cabinet 104 has the following function: when a chemical having combustibility, toxicity, corrosiviness, or some other similar nature leaks from the process cylinder 105 or the like, the cabinet 104 prevents the chemical from diffusing to the outside of the cylinder cabinet 104.

The process cylinder 105 is provided with: a valve 108 and a joint 109 arranged between the manifold A 107 and the process cylinder. 105 in the path wherein the chemical is supplied; and a valve 110 and a joint 111 arranged between the manifold A 107 and the process cylinder 105 in the path wherein the chemical is supplied. The pipe system is provided with: a valve 112 and a liquid mass flow 121 between the reaction chamber 102 and the manifold A 107 and near the manifold A 107; an injection valve 122; and a valve 123 arranged near the reaction chamber 102. A heater 124 is formed in the sphere from the injection valve 122 via the valve 123 to the reaction chamber 102. The pipe system is also provided with: a valve 114 arranged between a pressure feed gas port 113 and the manifold A 107 and near the manifold A 107; and a valve 116 arranged between a vent gas port 115 and the manifold A 107 and near the manifold A 107. Furthermore, the pipe system is provided with: a valve 120 arranged between a carrier gas port 119 and the injection valve 122 and neat the injection valve 122; and a valve 118 between a vacuum exhaust port 117 and the injection valve 122 and near the injection valve 122.

According to such a structure in the chemical supplying technique which the inventors have been investigated, the pressure of the sphere (inside space) in the process cylinder 105 is made high when pressure feed gas is fed into the process cylinder 105. As a result, the chemical 103 is supplied from the process cylinder 105 into the reaction chamber 102 through the path wherein the chemical is supplied.

When the chemical 103 inside the process cylinder 105 gets empty or turns into a small amount, this cylinder 105 is exchanged into a new process cylinder filled with a new chemical of the same kind. Specifically, the process cylinder 105 and manifold A 107 are separated from the joints 109 and 111, and thereafter this cylinder 105 is exchanged into a new process cylinder filled with a new chemical of the same kind. The chemical 103 such as TDMAT, which is a starting material for CVD, has combustibility, toxicity or the like; therefore, it is necessary to purge the chemical present in the pipe system, which includes the manifold A 107, with, for example, helium (He) gas introduced from, for example, the pressure feed gas port 113 before the exchange of the process cylinder 105. After the exchange of the process cylinder 105, it is necessary to purge the air present at the time of the exchange in the pipe system, which includes the manifold A 107, with, for example, nitrogen (N₂) gas introduced from, for example, the pressure feed gas port 115. The purging causes the remaining chemical to be prevented from becoming alien substances.

However, in the case that a chemical which has a low vapor pressure and is present in a liquid state at ambient temperature, for example, TDMAT is used as a starting material for CVD, the chemical may remain in the pipe system, which includes the manifold A 107, or the like. It is therefore necessary to carry out the step of repeating purging as described above to some degree, the step of heating the pipe system, which includes the manifold A 107, and the valves by means of a heat mechanism so as to promote the gasification of the chemical, thereby making the discharge of the chemical easy, the step of exchanging the manifold A 107, which is composed of the pipes and valves, into a new manifold at the same time when the process cylinder 105 is exchanged, and other steps.

When the process cylinder 105 is exchanged into a new process cylinder in the case that the chemical 103, such as TDMAT, is lost in the process cylinder 105 as described above, the CVD machine 101 needs to be stopped for a long term, for example, about 3 days for sufficient purging or check of the leakage since the exchange of the process cylinder is performed by a worker.

Accordingly, in order to shorten the period when the CVD machine is stopped, it would be useful neither to exchange the process cylinder, which is a sealed contained arranged in the cylinder cabinet in the CVD machine, nor the manifold included in the pipe system.

Thus, the inventors have further investigated a chemical supplying technique wherein even if a process cylinder of a CVD machine, in which a chemical which is a starting material for CVD is stored, becomes empty, a chemical supplying device is used without exchanging any process cylinder as described above to supply the chemical into the process cylinder. FIG. 5 is an explanatory view-of an example of a CVD machine and a chemical supplying device which are applied to a chemical supplying technique which the inventors have investigated.

The chemical supplying technique, which is not known in the prior art but has been investigated by the inventors, is roughly described with reference to FIG. 5. In the case of forming, for example, a TiN film in a reaction chamber 10 of a CVD machine 51, a chemical 38 such as TDMAT, which is a starting material for CVD, is supplied from a process cylinder 8 which is a sealed container arranged inside a cylinder cabinet 2 in the CVD machine 51. Thereafter, even if the process cylinder 8 of the CVD machine 51, wherein the chemical 38, which is a starting material for CVD, is stored, becomes empty, a chemical supplying device 1 is used to supply a chemical 36 into the process cylinder 8 from a fixed cylinder 6, which is a sealed container arranged in the chemical supplying device 1. In the case that, for example, a TiN film is formed in a reaction chamber 11 of the CVD machine 51 in the same manner as in the case that a film is formed in the reaction chamber 10, a chemical such as TDMAT, which is a starting material for CVD, is supplied from a process cylinder 9, which is a sealed container arranged inside a cylinder cabinet 3.

As illustrated in FIG. 5, the cylinder cabinet 2 in the CVD machine 51 is provided with: the process cylinder 8, in which the chemical 38, such as TDMAT, is stored (fully put); and a pipe system made to comprise a manifold A 40 connected to the process cylinder 8. The process cylinder 8 is provided with a valve 26 between the manifold A 40 and the process cylinder 8 in a path wherein the chemical 38 is supplied into the reaction chamber 10.

The chemical supplying device 1 for supplying a chemical into the CVD machine 51 has, inside a chassis thereof, the fixed cylinder 6 and an exchange cylinder 7, which are two sealed containers. When a chemical 37 in the exchange cylinder 7 is pressured with, for example, helium (He) gas from a pressure feed gas port 52, the chemical 37 is supplied from the exchange cylinder 7 to the fixed cylinder 6. Furthermore, when the chemical 36 in this fixed cylinder 6 is pressured with, for example, He gas from a pressure feed gas port 53, the chemical 36 is supplied from the fixed cylinder 6 to the process cylinder 8 through a manifold B 41 composed of pipes and valves. The chemical 36 in the fixed cylinder 6 is supplied into the process cylinder 8 inside the cylinder cabinet 2 or the process cylinder 9 inside the cylinder cabinet 3 by the opening or closing of a valve 12 and a valve 13.

According to such a structure in the chemical supplying technique which the inventors have investigated, the chemical 36 can be supplied from the chemical supplying device 1 to the process cylinder 8 without exchanging the process cylinder 8 even if the process cylinder 8 of the CVD machine 51, in which the chemical 38, which is a staring material for CVD, is stored, becomes empty.

However, in the case of forming, for example, a TiN film in the reaction chamber 10 of the CVD machine 51, it takes, for example, a term of about one month that the process cylinder 8 filled sufficiently with the chemical 38 becomes empty. Accordingly, the chemical 36 is present as it is for about one month in a connecting pipe 39 and the manifold B 41 which constitute the path wherein the chemical 36 is supplied from the chemical supplying device 1 to the process cylinder 8. As described above, the chemical 36 such as TDMAT, which is a starting material for CVD, has combustibility, toxicity or the like; therefore, it is not preferred from the viewpoint of safety and others that the chemical 36 is caused to be present as it is for about one month. In the case that the chemical 38 is sufficiently filled into the process cylinder 8 and subsequently the connecting pipe 39, for connecting the chemical supplying device 1 and the cylinder cabinet 2 in the CVD machine 51 to each other, the manifold B 41, and the process cylinder 8 are fitted up or taken off (that is, the connecting pipe 39, the manifold B 41 and the process cylinder 8 are exchanged because of a trouble such as leakage), it would be necessary to stop the CVD machine 51 for a long term for sufficient purging, the check of the leakage, or vacuum-drawing or other steps, as described above.

An object of the present invention is to provide a technique making it possible that even if a process cylinder of a CVD machine, wherein a chemical which is a starting material for CVD is stored, becomes empty, a chemical of the same kind can be filled into the process cylinder in a short time without exchanging the process cylinder.

The above-mentioned object and other objects of the invention and new characteristics thereof will be made apparent by way of the description of the present specification and the attached drawings.

A typical aspect of the invention disclosed in the present application is briefly described as follows.

The invention is a supplying method of a chemical, which is performed by comprising a first path in which the chemical is supplied to a sealed first container arranged in a device for conducting treatment by chemical reaction using the chemical from a sealed second container arranged in a chemical supplying device and a second path connected to the first path, the method comprising the following steps: the chemical in the second container is first pressured with a first gas in the first path comprising a first pipe, thereby supplying the chemical from the second container to the first container; and next the pressure inside the first container is lowered and subsequently a second gas is introduced from the second path comprising a second pipe to the first path, thereby returning the chemical remaining in the first path to the first or second container.

Advantageous effects of the typical aspect of the invention disclosed in the present application are briefly as follows.

Even if a process cylinder of a CVD machine, wherein a chemical which is a starting material for CVD is stored, becomes empty, the chemical supplying method of the invention makes it possible to fill a chemical of the same kind into the process cylinder in a short time without exchanging the process cylinder.

### BRIEF DESCRIPTION OF THE DRAWINGS

FIG. 1 is an explanatory view illustrating a CVD machine and a chemical supplying device to which a chemical supplying technique in an embodiment of the present invention is applied.

FIG. 2 is an explanatory view illustrating the CVD machine and the chemical supplying device illustrated in FIG. 1 in more detail.

FIG. 3 is a flowchart of the chemical supplying technique in the embodiment of the invention.

FIG. 4 is an explanatory view illustrating an example of a CVD machine to which a chemical supplying technique which the inventors have investigated is applied.

FIG. 5 is an explanatory view illustrating an example of a CVD machine and a chemical supplying device to which the chemical supplying technique which the inventors have investigated is applied.

### DETAILED DESCRIPTION OF THE PREFERRED EMBODIMENTS

Embodiments of the present invention will be described in detail with reference to the drawings hereinafter. In all figures for explaining the embodiments, in principle the same reference numbers are attached to the same members, and repeated description thereof is omitted.

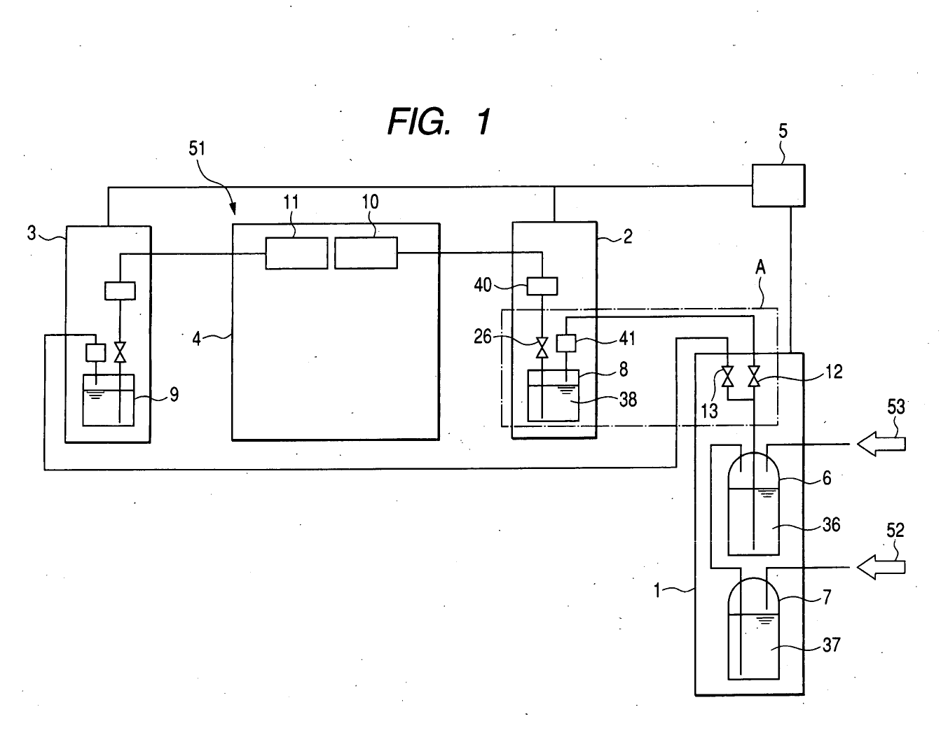

First, a chemical supplying technique in an embodiment of the invention is roughly described with reference to FIG. 1, which is an explanatory view illustrating a CVD machine and a chemical supplying device to which the chemical supplying technique in the embodiment of the invention is applied.

When, for example, a TiN film is formed in a reaction chamber 10 of a CVD machine 51, which is a machine for conducting treatment using chemical reaction, a chemical 38 which is a starting material for CVD, such as tetrakis(dimethylamino)titanium (TDMAT:Ti(N(CH₃)₂)₄), is supplied from a process cylinder 8, which is a sealed container (first container) arranged inside a cylinder cabinet 2 in the CVD machine 51. Furthermore, even if the process cylinder of the CVD machine, wherein the chemical, which is a starting material for CVD, is stored, becomes empty, a chemical supplying device 1 is used to supply a chemical 36 from a fixed cylinder 6, which is a sealed container (second container) arranged in the chemical supplying device 1, to the process cylinder 8. In the case that, for example, a TiN film is formed in a reaction chamber 11 of the CVD machine 51 in the same manner as in the case of the film-formation in the reaction chamber 10, a chemical which is a starting material for CVD, for example, TDMAT is supplied from a process cylinder 9, which is a sealed container arranged inside a cylinder cabinet 3.

As illustrated in FIG. 1, the cylinder cabinet 2 in the CVD machine 51 is provided with: the process cylinder 8, in which the chemical 38, such as TDMAT, is stored (fully put); and a pipe system made to comprise a manifold A 40 connected to the process cylinder 8. The process cylinder 8 is provided with a valve 26 between the manifold A 40 and the process cylinder 8 in a path wherein the chemical 38 is supplied into the reaction chamber 10.

The chemical supplying device 1 for supplying a chemical into the CVD machine 51 has, inside a chassis thereof, the fixed cylinder 6 and an exchange cylinder 7, which are two sealed containers. When a chemical 37 in the exchange cylinder 7 is pressured with, for example, helium (He) gas from a pressure feed gas port 52, the chemical 37 is supplied from the exchange cylinder 7 to the fixed cylinder 6. Furthermore, when the chemical 36 in this fixed cylinder 6 is pressured with, for example, He gas from a pressure feed gas port 53, the chemical 36 is supplied from the fixed cylinder 6 to the process cylinder 8 through a manifold B 41 composed of pipes and valves. The chemical 36 in the fixed cylinder 6 is supplied into the process cylinder 8 inside the cylinder cabinet 2 or the process cylinder 9 inside the cylinder cabinet 3 by the opening or closing of a valve 12 and a valve 13.

According to such a structure in the chemical supplying technique which the inventors have investigated, the chemical 36 can be supplied from the chemical supplying device 1 to the process cylinder 8 without exchanging the process cylinder 8 by the control of the valves 12 and 13 and the manifold B 41 even if the process cylinder 8 of the CVD machine 51, in which the chemical 38, which is a staring material for CVD, is stored, becomes empty.

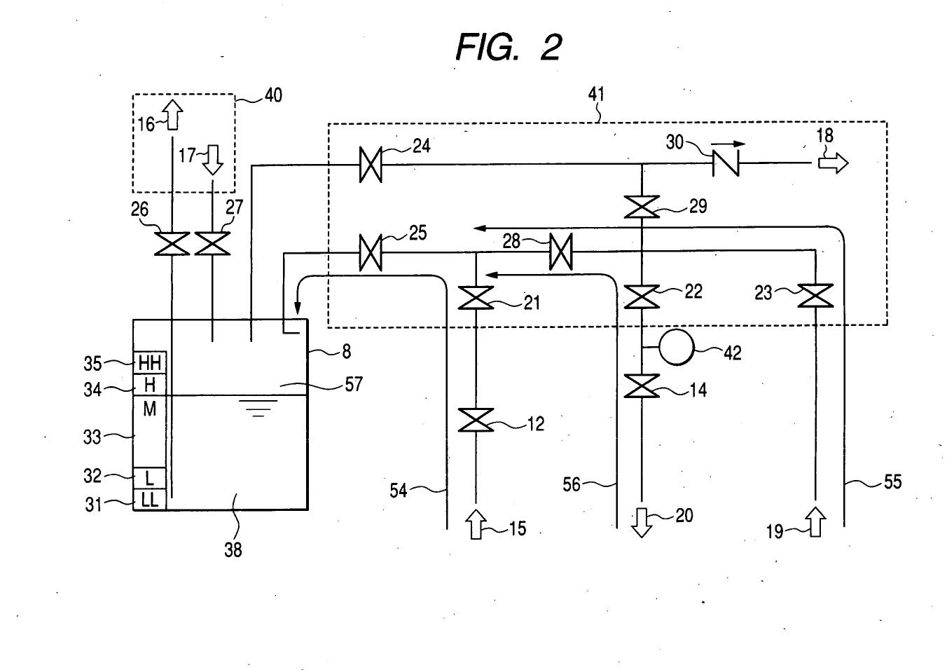

The following describes the chemical supplying technique in the embodiment of the invention in detail with reference to FIG. 2, which is an explanatory view illustrating the CVD machine and the chemical supplying device in FIG. 1 in more detail. An area A in FIG. 1 is illustrated in more detail.

As illustrated in FIG. 2, the process cylinder 8, which is a sealed container (first container) arranged in the CVD machine, is a small-sized cylindrical sealed container having a volume of, for example, 1.2 liters. The residual amount of the chemical 38 stored in the process cylinder 8 is indicated therein at five stages, which are an LL level 31, an L level 32, an M level 3, an H level 34 and an HH level, which are described in order from a small residual amount toward a larger residual amount.

Through the valve 26 arranged in the pipe which penetrates the ceiling of the container body of the process cylinder 8 and has a lower end positioned near the bottom of the container body, the amount of the chemical 38 supplied from the process cylinder 8 to a chemical port 16 at the side of the CVD machine is adjusted. The chemical port 16 is positioned between the valve 26 and the manifold A 40 in the path wherein the chemical 38 is supplied from the process cylinder 8 to the reaction chamber 10 of the CVD machine 51 illustrated in FIG. 1.

Through a valve 27 arranged in the pipe which penetrates the ceiling of the container body of the process cylinder 8 and has a lower end positioned above the HH level 35, the amount of a gas (first gas), such as He gas, fed from the pressure feed gas port to the process cylinder 8 by pressure is adjusted. In FIG. 1, the pressure feed gas port 17 is omitted since the port is present inside the manifold B 41.

Through a valve 24 arranged in the pipe which penetrates the ceiling of the container body of the process cylinder 8 and has a lower end positioned above the HH level 35, a gas is sent from the process cylinder 8 through a check valve 30 into a vent port 18 so as to be discharged, thereby lowering the pressure of a sphere 57 inside the process cylinder 8 into, for example, the pressure of the atmosphere. In FIG. 1, the valve 24, the check valve 30 and the vent port 18 are omitted.

Through a valve 25, a valve 21 and the valve 12 arranged in the pipe which penetrates the ceiling of the container body of the process cylinder 8 and has a lower end positioned above the HH level 35, the amount of the chemical 38 supplied from a chemical port 15 at the side of the chemical supplying device to the process cylinder 8 is adjusted. A reference number 54 represents a path (first path) made of a pipe (first pipe) wherein the chemical is supplied to the process cylinder 8, which is a sealed container (first container) arranged in the CVD machine, which is a machine for conducting treatment by chemical reaction, from the fixed cylinder, which is a sealed second container-arranged in the chemical supplying device. The chemical port 15 is present between the valve 12 and the fixed cylinder 6 in the path wherein the chemical 36 is supplied from the fixed cylinder 6 to the process cylinder 8 illustrated in FIG. 1.

Through valves 23 and 28, the amount of, for example, He gas is adjusted, which is a gas (second gas) fed from a pressure feed gas port 19 to a pipe constituting the path 54 by pressure. A reference number 55 represents a path (second path) made of a pipe (second pipe) connected to the path 54. In FIG. 1, the valves 23 and 28 and the pressure feed gas port 19 are omitted since they are present inside the manifold B 41.

By means of the valves 14, 22 and 28 and a vacuum meter 42, the amount of a gas discharged by degassing of the pipe constituting the path 54 from the vacuum exhaust port 20 is adjusted. A reference number 56 represents a path (third path) made of a pipe (third pipe) connected to the path 54. The valves 22 and 28 are present inside the manifold B 41; thus, the valves together with the valve 14 and the vacuum meter 42 are omitted in FIG. 1.

A valve 29 and a pipe therefor are arranged to bridge a path in which a gas is sent from the process cylinder 8 through a check valve 30 to the vent port 18 so as to be discharged and the path 55 in order to prevent damage of the check valve 30 based on the chemical such as TDMAT. In other words, a gas in the sphere 57 inside the process cylinder 8 is discharged through the valve 24 and the check valve 39, whereby the check valve 30 may be damaged; therefore, a valve 29 is arranged in order to purge the check valve 30 with, for example, He gas from the pressure feed gas port 19. The valve 29 is omitted in FIG. 1 since the valve 29 is present inside the manifold B 41.

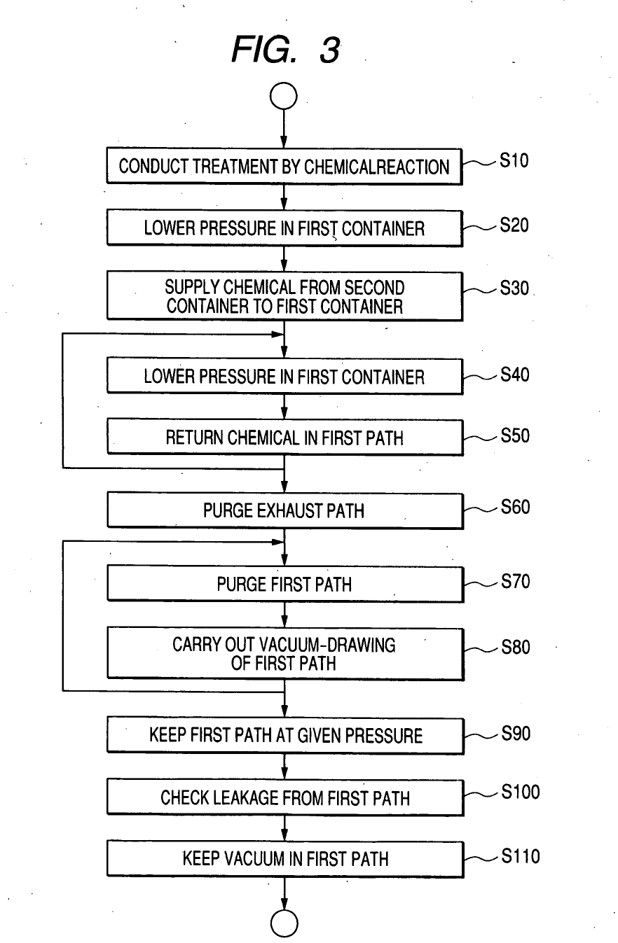

The following describes a chemical supplying method in the embodiment of the invention with reference to FIGS. 1 to 3. FIG. 3 is a flowchart of the chemical supplying method in the embodiment of the invention.

First, for example, a TiN film is formed in, for example, the reaction chamber 10 of the CVD machine 51, which is a machine for conducting treatment by chemical reaction (step S10). When the TiN film is formed in the reaction chamber 10 of the CVD machine 51, the chemical 38 such as TDMAT, which is a starting material for CVD, is supplied from the process cylinder 8, which is a sealed container arranged inside the cylinder cabinet 2 in the CVD machine 51. In other words, when, for example, He gas is sent from the pressure feed gas port 17 into the process cylinder 8, the pressure of the sphere 57 inside the process cylinder 8 is made high, thereby supplying the chemical 38 from the process cylinder 8 into the reaction chamber 10, so as to be used.

Until the chemical 38 inside the process cylinder 8 becomes empty or turns into a small amount, the state that the chemical 36 is not supplied from the chemical supplying device 1 to the process cylinder 8 (standby state) continues. At this time, in the path 54, the pipe between the valves 12 and 25 is kept in a vacuum-drawing state. Specifically, when the valves 21, 28, 22 and 14 are each turned into an “open” state and vacuum-drawing from the vacuum exhaust port 20 in the path 56 connected to the path 54 is carried out, the pipe (connecting pipe) between the valves 12 and 25 is kept in a vacuum-drawing state.

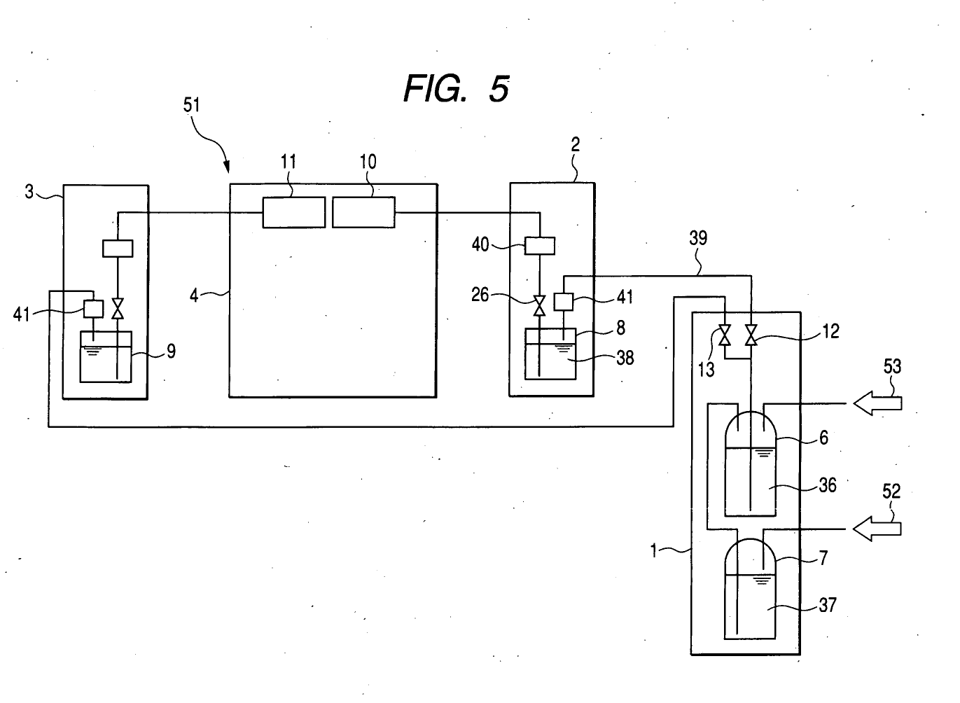

In the CVD machine and the chemical supplying device, illustrated in FIG. 5, to which the chemical supplying technique which the inventors have investigated is applied, the chemical remains in the connecting pipe 39 in the above-mentioned standby state. This chemical such as TDMAT, which is a starting material for CVD, has combustibility, toxicity or the like; therefore, it is not preferred from the viewpoint of safety and quality to cause the chemical to be present as it is in the connecting pipe 39 for a long term. In the present embodiment, however, in the standby state the pipe (connecting pipe) between the valves 12 and 25 is kept in a vacuum-drawing state; thus, it can be stated that safety, and the quality of the supplying device and the chemical are high.

Subsequently, the valves 21, 28, 22 and 14 are each turned into a “close” state before the chemical 36 is supplied from the fixed cylinder 6 to the process cylinder 8. Next, the pressure of the sphere 57 in the process cylinder 8, which is raised by supplying the chemical 38 into the reaction chamber 10, is lowered into, for example, the pressure of the atmosphere by turning the valve 24 into an “open” state (step S20). Thereafter, the valve 24 is again turned into a “close” state.

Subsequently, the chemical 36 is supplied from the fixed cylinder 6 of the chemical supplying device 1 to the process cylinder 8 of the CVD machine 51 (step S30). The first path 54, wherein the chemical 36 is supplied from the fixed cylinder 6, which is a sealed second container arranged in the chemical supplying device 1, to the process cylinder 8, which is the sealed first container arranged in the CVD machine 51, is made of the first pipe; accordingly, when the valves 12, 21 and 25 in this path 54 are each turned into an “open” state and the chemical 36 inside the fixed cylinder 6 is pressured with He gas, which is the first gas, having a pressure of, for example, about 38 psi (0.26 Pa), the chemical 36 is supplied from the fixed cylinder 6 to the process cylinder 8 up to the H level 34. Even if the chemical 38 is supplied at a level not less than the H level (first level) in the process cylinder 8, the pressure raised in the process cylinder 8 can become a constant pressure, thereby stopping the supply of the chemical 38 at the HH level (second level) in the process cylinder 8. The pressure at which the supply of the chemical 38 is stopped can be set to the same pressure as He gas fed into the process cylinder 38 by pressure has, for example, about 38 psi (0.26 Pa). Thus, overflow of the chemical 38 can be prevented.

Subsequently, the pressure in the process cylinder 8 is lowered (step S40). Specifically, since the pressure of the sphere 57 in the process cylinder 8 is high after the chemical 36 is supplied into the process cylinder 8, the valve 24 is turned into an “open” state so as to lower the pressure into, for example, the pressure of the atmosphere, and subsequently the valve 24 is turned into a “close” state.

Subsequently, for example, He gas (second gas) is introduced from the path 55, which is connected to the path 54 and made of the second pipe, into the path 54 to pressure the chemical present in the path 54 (step S50). Specifically, the valves 25, 28 and 23 are each turned into an “open” state to return the chemical remaining in the pipe of the path 54 into the process cylinder 8 or the fixed cylinder 6 by means of He gas, and subsequently the valves 25, 28 and 23 are each turned into a “close” state.

Thereafter, the following steps maybe repeated: the step of lowering the pressure in the process cylinder 8 (step S40); and the step of introducing, for example, He gas (second gas) from the path 55, which is connected to the path 54 and made of the second pipe, into the path 54 to pressure the chemical present in the path 54 (step S50). When the steps are repeated several times, the chemical remaining in the pipe of the path 54 can be further discharged and removed.

Subsequently, the valves 23 and 29 are each turned into an “open” state to introduce, for example, He gas into the path from the pressure feed gas port 19 through the check valve 30 to the vent port 18 to purge the exhaust path from the check valve 30 to the vent port 18 (step S60). Such purging makes it possible to prevent damage of the check valve 30 by action of the chemical such as TDMAT.

Subsequently, for example, He gas is introduced from the path 55 to the path 54 to purge the path 54 (step S70). Specifically, the valves 23, 28 and 21 are each turned into an “open” state to introduce, for example, He gas from the pressure feed gas port 19, thereby purging the pipe of the path. 54. Thereafter, the valves 23, 28 and 21 are each turned into a “close” state.

Subsequently, vacuum-drawing from the third path 56, which is connected to the path 54 and is made of the third pipe, is carried out to lower the pressure in the path 54 (step S80). Specifically, the valves 14, 22, 28 and 21 are each turned into an “open” state to carry out vacuum-drawing of the pipe of the path 54 from the vacuum exhaust port 20, and then the valves 14, 22, 28 and 21 are each turned into a “close” state.

Thereafter, the following steps maybe repeated: the step of introducing, for example, He gas from the path 55 to the path 54 to purge the path 54 (step S70); and the step of lowering the pressure in the path 54 by carrying out vacuum-drawing from the third path 56, which is connected to the path 54 and is made of the third path (step S80). When the steps are repeated several times, the chemical remaining in the pipe of the path 54 can be further discharged and removed.

Subsequently, the pressure in the path 54 is kept at a given pressure by carrying out vacuum-drawing from the path 56 connected to the path 54. Specifically, the valves 14, 22, 28 and 21 are each turned into an “open” state to carry out vacuum-drawing of the pipe of the path 54 from the vacuum exhaust port 20, and then the valves 14, 22, 28 and 21 are each turned into a “close” state. The given pressure is preferably a pressure from 0.01 to 3 Pa, which is adjusted with, for example, a dry pump. A higher-degree vacuum pump may be used to make a high-degree vacuum. However, the pressure is made in the range of 0.01 to 3 Pa with the dry pump, considering costs for facilities, time necessary for the vacuum-drawing, and others.

Subsequently, leakage from the pipe of the path 54 is checked (step S100). As a result, the system turns into the above-mentioned standby state.

Subsequently, vacuum-drawing from the path 56 connected to the path 54 may be carried out to keep the pressure in the path 54 at a given pressure (step S110).

The above-mentioned chemical supplying method of the embodiment of the present invention can be automatically controlled. The method can be operated with a remote operation controller 5. Furthermore, even if the chemical 38 is supplied at a not less than the H level (first level) 34 in the process cylinder 8, the pressure raised in the process cylinder 8 can become a constant pressure so that the supply of the chemical 38 can be stopped at the HH level (second level) in the process cylinder 8 and further a warning can be issued by the remove operation controller 5. The pressure at which the supply of the chemical 38 is stopped can be set to the same pressure as He gas fed into the process cylinder 38 by pressure has, for example, about 38 psi (0.26 Pa). Thus, overflow of the chemical 38 can be prevented.

In the chemical supplying technique of the embodiment of the invention, it is neither necessary to exchange the process cylinder, which is a sealed container arranged in the cylinder cabinet in the CVD machine, nor the manifold fitted above the process cylinder. It is therefore possible to remove a long stop period of the CVD machine necessary for the chemical supplying technique which the inventors have investigated, that is, a stop period of, for example, about 3 days per month per CVD machine for exchanging the process cylinder and the manifold fitted up to the process cylinder. The removal of the stop period makes it possible that an exchanging worker is also engaged in a different work. When, for example, a TiN film is formed as a metal film for contact plugs of transistors which constitute a semiconductor device, such as an LSI, in the reaction chamber in the CVD machine, the production of the semiconductor device becomes smooth by use of the chemical supplying technique of the embodiment of the invention.

In the chemical supplying technique which the inventors have investigated, a chemical having a volume of, for example, 1.2 liters is filled in each process cylinder arranged in a cylinder cabinet in a CVD machine. Therefore, for process-cylinder-exchange, it is necessary that a chemical put in a process cylinder is purchased every 1.2 liters. However, according to the chemical supplying technique of the embodiment of the invention, it becomes unnecessary to exchange any process cylinder. Thus, a chemical can be purchased in a large amount, for example, in an amount of 4 liters at each time. As a result, costs of the chemical can be reduced.

In the chemical supplying technique which the inventors have investigated, a process cylinder arranged in a cylinder cabinet in a CVD machine is exchanged in the state that a chemical in the process cylinder remains to some extent (the residual amount of the chemical: for example, about 100 mL) Thus, the chemical may be wasted. However, according to the chemical supplying technique of the embodiment of the invention, an exchange cylinder in which a chemical is put is exchanged but no process cylinder needs to be exchanged. Thus, costs for production of a film can be decreased.

In the chemical supplying technique of the embodiment of the invention, a chemical remaining in pipes and valves connected to a process cylinder, a fixed cylinder or an exchange cylinder is purged with gas at the time of chemical-exchange and subsequently vacuum-drawing is carried out. This standby state is kept. Accordingly, it is neither necessary to exchange a process cylinder, which is a sealed container arranged in a cylinder cabinet in a CVD machine, nor exchange a manifold fitted to the process cylinder into a new or reproduced manifold. It is therefore possible to remove member costs for the manifold necessary in the chemical supplying technique which the inventors have investigated.

The above has specifically described the invention which has been made by the inventors on the basis of the embodiment thereof. Of course, however, the invention is not limited to the embodiment and can be variously modified as long as the modifications do not depart from the subject matter thereof.

In the above-mentioned embodiment, for example, the case that a CVD machine is used as the machine for conducting treatment by chemical reaction has been described. However, a sputtering machine, an etching machine or the like may be used.

In the embodiment, for example, the case that two reaction chambers are arranged in the CVD machine has been described. However, a reaction chamber or plural chambers such as three chambers may be used. Even if one or more process cylinders are arranged correspondingly to the reaction chamber(s), the chemical supplying method of the invention makes it unnecessary to exchange the process cylinder(s), which are one or more sealed containers arranged in a cylinder cabinet in the CVD machine, nor exchange one or more manifolds fitted to the process cylinder(s).

In the embodiment, for example, the case that TDMAT is used as the chemical has been described. However, a chemical having a low vapor pressure can be used, examples of which include tetrkis(dialkylamino)titanium (TDAAT), tetrakis(diethylamino)titanium (TDEAT), and tetrakis(ethylmethylamino)titanium (TEMAT).

When, for example, a thermally decomposable chemical having a low vapor pressure is used, a chemical supplying method described below can also be performed in the CVD machine.

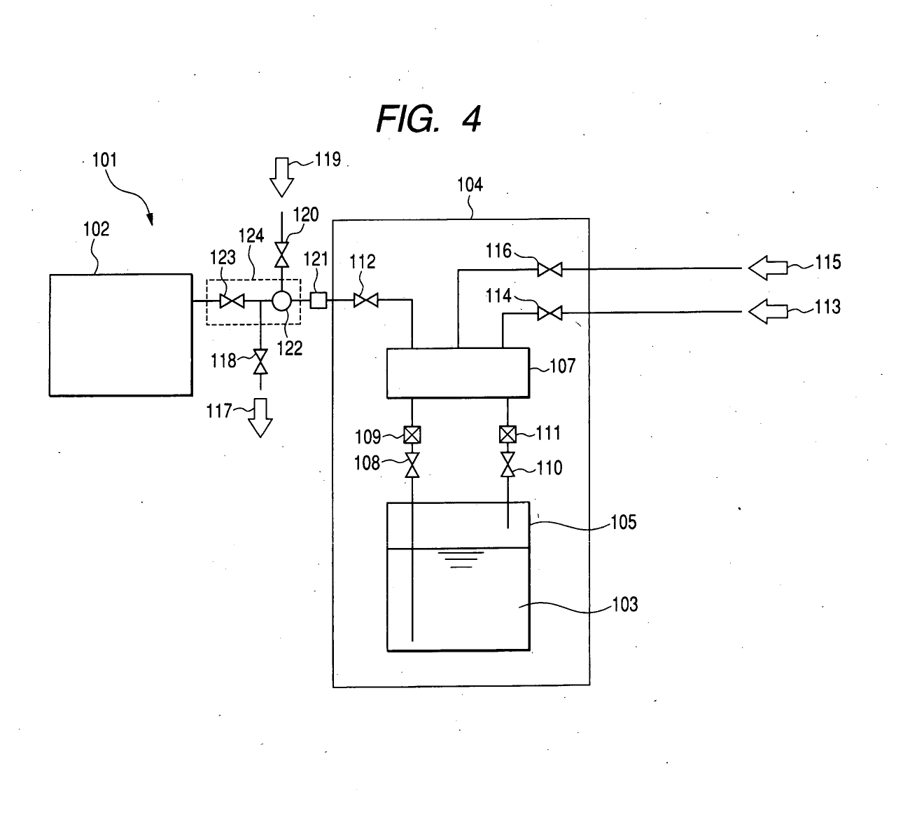

When a given amount of a thermally decomposable chemical having a low vapor pressure, such as TDMAT, is supplied into the reaction chamber 102 through the liquid mass flow 121 and the injection valve 122 illustrated in FIG. 4, the heater 124 is used to make the vapor pressure high so as to keep the amount of the chemical. In this case, the temperature of the heater 124 is usually set to a temperature lower than the thermal decomposition temperature of the chemical for the following reason: if the chemical is kept at a higher temperature for a long time, the chemical decomposes thermally. For example, TDMAT decomposes thermally at about 90° C. at such a rate that the decomposition is visible. When TDMAT is kept at about 50° C., thermal decomposition is apparently generated in about 6 months. Thus, when TDMAT is used as the chemical, the heater 124 is turned on and the temperature thereof is usually controlled into the range from 60 to 80° C.

In the meantime, a process machine, for example, the CVD machine 101 may be stopped for several hours or several days for non-routine works other than product-producing works, such as a work for exchanging the process cylinder 105 and cleaning of the reaction chamber 102, or may be stopped for the same period as a product-awaiting time. In the case that at this time a chemical remains in the pipe from the process cylinder 105 to the reaction chamber 102 in the CVD machine 101, or in some other section, thermal decomposition of the chemical is partially caused by effect of the heater 124 or the heater attached to the manifold A 107. Furthermore, the sheet of the liquid mass flow 121 or the injection valve 122 is usually made of resin; therefore, by the passage of a long term the sheet may easily undergo deformation or the like in accordance with the temperature applied to the sheet even if the temperature is not more than the heat resistant temperature.

Thus, in the case that no chemical is supplied in the reaction chamber 102, such as a case where the CVD machine 101 is in the above-mentioned standby state or a case where the CVD is subjected to a non-routine work, the heater 124 present between the process cylinder 105 and the reaction chamber 102, and the heater attached to the manifold A 107 are turned off, the inside of the liquid mass flow 121 and the injection valve 122 is degassed through the valve 118 from the vacuum exhaust port 117 so as to carry out vacuum-drawing of the inside and continue the vacuum-drawing. This makes it possible to discharge out the remaining chemical and so on to prevent a breakdown of the liquid mass flow 121 or the injection valve 122 which is caused by thermal decomposition of the chemical or deformation of the resin.

The present invention is widely used in chemical supplying techniques.

What is claimed is:

1. A supplying method of a chemical, which is performed by comprising: a first path in which the chemical is supplied into a sealed first container arranged in a device wherein treatment is conducted by chemical reaction using the chemical from a sealed second container arranged in a chemical'supplying device; and a second path connected to the first path,
the method comprising the steps of:
(a) pressuring the chemical in the second container by action of a first gas in the first path comprising a first pipe, thereby supplying the chemical from the second container into the first container;
(b) lowering the pressure in the first container; and
(c) introducing a second gas from the second path comprising a second pipe into the first path after the step (b), thereby returning the chemical remaining in the first path into the first or second container.

2. The chemical supplying method according to claim 1,
wherein the steps (b) and (c) are repeated.

3. The chemical supplying method according to claim 1,
wherein even if the chemical is supplied at not less than a first level in the first container in the step (a), the raised pressure in the first container becomes a constant pressure, thereby stopping the supply of the chemical at a second level in the first container.

4. The chemical supplying method according to claim 1,
wherein after the step (b) the pressure in the first container is the pressure of the atmosphere.

5. The chemical supplying method according to claim 1,
wherein the chemical is TDMAT.

6. The chemical supplying method according to claim 1,
wherein the first and second gases are each He gas.

7. The chemical supplying method according to claim 1,
further comprising the steps of:
(d) introducing the second gas from the second path to the first path, thereby purging the first path; and
(e) performing vacuum-drawing from a third path which is connected to the first path and comprises a third pipe after the step (d), thereby lowering the pressure in the first path.

8. The chemical supplying method according to claim 7,
wherein the steps (d) and (e) are repeated.

9. The chemical supplying method according to claim 7, further comprising a step of:
(f) performing vacuum-drawing from the third path, thereby keeping the pressure in the first path at a given pressure.

10. The chemical supplying method according to claim 9,
wherein the given pressure ranges from 0.01 to 3 Pa.

11. The chemical supplying method according to claim 9, wherein a process from the step (a) to the step (f) isautomatically controlled.

12. The chemical supplying method according to claim 9,
wherein a process from the step (a) to the step (f) is operated with a remote operation controller.

13. The chemical supplying method according to claim 12,
wherein even if the chemical is supplied at not less than a first level in the first container in the step (a), the raised pressure in the first container becomes a constant pressure, thereby stopping the supply of the chemical at a second level in the first container and further issuing a warning by means of the remote operation controller.

14. A supplying method of a chemical in a CVD machine, the CVD machine comprising:
a liquid mass flow and an injection valve arranged in a path wherein the chemical is supplied from a sealed container arranged in the CVD machine to a reaction chamber of the CVD machine;
a first valve arranged near the liquid mass flow in the path and between the container and the liquid mass flow;
a second valve arranged near the reaction chamber in the path and between the injection valve and the reaction chamber;
a third valve arranged near the container in the path and between the first valve and the container;
a first heater for heating the sphere between the injection valve and the second valve in the path; and
a second heater for heating the sphere between the first valve and the second valve in the path,
the method comprising the step of:
keeping a vacuum in the sphere between the first valve and the second valve in the path or the sphere between the second valve and the third valve in the path when the chemical is not supplied into the reaction chamber.

15. The chemical supplying method according to claim 14,
wherein when the chemical is not supplied into the reaction chamber, the first and second heaters arranged between the first and second valves are turned off.
